(19) United States
(12) Patent Application Publication
(10) Pub. No.: US 2025/0388096 A1
(43) Pub. Date: Dec. 25, 2025

(54) Electrical Energy Store With a Plurality of Storage Strands and Disconnecting Devices Between the Storage Strands

(71) Applicant: Bayerische Motoren Wotoren Werke Aktiengesellschaft, Muenchen (DE)

(72) Inventors: Kevin CZYRKA, Muenchen (DE); Dominik GRUBER, Muenchen (DE); Bjoern WAHL, Muenchen (DE)

(21) Appl. No.: 18/879,674

(22) PCT Filed: Aug. 18, 2023
(86) PCT No.: PCT/EP2023/072762

§ 371 Date: Dec. 27, 2024

(30) Foreign Application Priority Data
Sep. 14, 2022 (DE) 10 2022 123 453.3

(51) Int. Cl. B60L 50/64; B60L 58/24; H01M 10/48

(52) U.S. Cl. CPC B60L 50/64; B60L 58/24; H01M 10/482; B60L 2240/545; H01M 2200/103; H01M 2220/20

(57) ABSTRACT

An electrical energy store for a motor vehicle includes at least two storage strands which extend geometrically adjacent to one another and each have a plurality of connected storage units which each have at least one storage cell; at least one strand connector for serially connecting the storage strands to a disconnecting device for detecting and interrupting a fault current circuit formed by an undesired electrical connection between two storage strands and by the at least one strand connector, where the disconnecting device has a controllable disconnecting unit for disconnecting the at least one strand connector and a current sensor for detecting a strand current flowing over the at least one strand connector; and a control device configured to detect at least one fault current circuit based on the detected strand current and to actuate the at least one disconnecting unit in order to interrupt the fault current circuit.

### BACKGROUND AND SUMMARY

The present disclosure relates to an electrical energy store for a motor vehicle for supplying power to at least one vehicle component of the motor vehicle. The electrical energy store comprises multiple interconnected storage units that each comprise at least one storage cell. The present disclosure additionally relates to a motor vehicle.

The present document is concerned with electrical energy stores for motor vehicles. By way of example, these can be used as traction batteries for electrified motor vehicles, that is to say electric or hybrid vehicles, and supply energy to at least one vehicle component, for example an electrical drive machine. Energy stores normally comprise a multiplicity of interconnected storage cells and generally have fault current disconnecting devices for short circuits that occur outside the stores. Additionally, there may be provision inside the stores for passive disconnecting elements that trip in the event of a spreading development of heat, for example caused by a fault current. However, certain geometrical arrangements of the storage cells in relation to one another can result in fault currents inside the energy store flowing not via the disconnecting elements but rather via parasitic fault current paths, which means that these fault currents cannot be interrupted by the disconnecting elements. Additionally, the parasitic current paths can have an undefined electrical resistance, and so these fault currents may be significantly lower than the rated current of the electrical energy store. Appropriate design of the disconnecting elements is therefore not possible. These undetected fault currents can lead, even when the electrical energy store is in a de-energized state, to critical hotspots locally and can result in a thermal event for the energy store.

An object of the present disclosure is to provide a simple solution to how fault currents inside an electrical energy store for a motor vehicle can be detected and disconnected particularly reliably.

This object is achieved according to the disclosure by way of an electrical energy store and a motor vehicle having the features disclosed herein. Advantageous embodiments of the disclosure are disclosed in the description and the figures.

An electrical energy store for a motor vehicle is used to supply power to at least one vehicle component of the motor vehicle. The electrical energy store comprises at least two geometrically adjacently extending store strings, each having multiple interconnected storage units that each comprise at least one storage cell. Additionally, the electrical energy store comprises at least one string connector for connecting the store strings in series with a disconnecting device for detecting and interrupting a fault circuit formed by an undesirable electrical connection between two store strings and the at least one string connector. The disconnecting device comprises a controllable disconnecting unit for disconnecting the at least one string connector and a current sensor for recording a string current flowing via the at least one string connector. Moreover, the electrical energy store comprises a control device designed to take the recorded string current as a basis for detecting the fault circuit and driving the disconnecting unit to interrupt the fault circuit.

The disclosure additionally relates to a motor vehicle having an electrical energy store according to the disclosure and at least one vehicle component electrically connected to the energy store. The electrical energy store is in particular a high-voltage energy store and is used as a traction battery for an electrified motor vehicle. The at least one vehicle component may be an electrical drive machine, for example, that is supplied with electrical energy for driving the motor vehicle by the traction battery. The electrical energy store comprises multiple storage units, or battery units, that are arranged in strings. This means in particular that the storage units within a string are arranged in a geometrically linear manner, that is to say in a row or a column. The storage units are preferably connected up in series within the string. The storage units each comprise at least one storage cell, or battery cell. By way of example, each storage unit may also comprise an interconnection of multiple storage cells. Preferably, the storage cells are in the form of round cells. The storage cells may also be in the form of prismatic cells or pouch cells, however.

The strings are electrically connected up in series, but extend geometrically adjacently. In particular, the strings have the same direction of extension and run parallel to one another. This geometrical arrangement of the storage units within a respective string and of the strings in relation to one another means that each storage unit has in particular at least one adjacent storage unit in the same store string and at least one adjacent storage unit in an adjacent store string. The electrical energy store can additionally comprise at least one temperature control element for controlling the temperature of the storage cells, which temperature control element extends through the energy store transversely with respect to the direction of extension of the strings. In the case of round cells, there is provision in particular for multiple temperature control elements in the form of strip-shaped, wavy temperature control lines, regions of which are arranged abutting cylindrical cell housings of the storage cells. By way of example, the temperature control elements can carry a fluid for transporting away the waste heat from the storage cells and/or for transporting heat to the storage cells.

To connect up the strings, there is provision for at least one string connector. Said string connector may be in the form of a metal busbar, for example. The string connector connects two ends of two adjacent strings, which ends are adjacent transversely to the direction of extension. A first and a last string of the electrical energy store are connected to connections in the form of a positive pole and a negative pole of the electrical energy store. If the electrical energy store comprises at least three adjacently extending strings, a total current path of the electrical energy store runs in a geometrically meandrous manner from one connection of the electrical energy store, through the interconnection of storage units, to the other connection of the electrical energy store.

This special arrangement of the strings in relation to one another can result in parasitic, undesirable fault current paths being formed between two, directly adjacent or spaced, strings. Such a fault current path can result from defective insulation of the at least one temperature control element, for example. The at least one temperature control element normally comprises a metal fluid conductor that, due to the abutting arrangement of the temperature control element against the metal cell housings of the storage cells, comprises an insulating layer. If said insulating layer is defective at two locations in the region of two strings that run parallel, the parasitic fault current path between these strings can be formed by way of the metal fluid conductor. Parasitic current paths can also be formed between two strings in another way, for example as a result of electrically conductive particles deposited in the energy store. A parasitic current path of this kind and the at least one string connector connecting the strings are used to form a parasitic fault circuit in which a fault current can circulate even when the electrical energy store is in a de-energized state, for example a state decoupled from the at least one vehicle component. This store-internal fault current can lead to local overheating and thus to a thermal event for at least one storage cell, which in the worst case can result in thermal runaway for the whole electrical energy store.

To prevent this, the fault circuit is interrupted when the fault current path is detected. To this end, in particular each string connector of the electrical energy store comprises a disconnecting device that can be driven by the control device. By way of example, the control device may be integrated in a store-internal or store-external control unit or may be in the form of a separate control unit. Each disconnecting device comprises at least one controllable disconnecting unit. The controllable disconnecting unit is preferably in the form of a pyro fuse. By way of example, such a pyro fuse comprises an ignition unit, or ignition capsule, that activates a disconnecting element to mechanically disconnect the string connector. The ignition capsule can be ignited by the control device. Additionally, each disconnecting device comprises a current sensor that records the string current flowing via the string connector. The recorded string current can be taken as a basis for detecting whether there is a parasitic current path that leads from this string to another string.

By way of example, the electrical energy store can comprise a total current sensor for recording a total current flowing through the interconnection of the strings, wherein the control device is designed to compare the string current with the total current and to detect the fault circuit if the string current differs from the total current by more than a predetermined threshold value. As the strings are connected up in series, the string currents in the fault-free state ought to correspond to the total current. If at least one of the string currents differs from this total current, this is an indication of the presence of a fault circuit. As an alternative or in addition to the comparison with the total current, when there are at least three store strings connected up in series, the control device may be designed to compare the string currents with one another, to take the comparison as a basis for detecting at least one fault circuit and to drive the disconnecting unit of the respective string connector to interrupt the relevant fault circuit. As the string currents in the series connection ought also to be the same when there is no fault, the fault circuit can also be detected on the basis of a difference in the fault currents among one another and/or in relation to the total current. The control device then drives the disconnecting unit of the string connector carrying the string current that differs from the total current. This disconnects the fault circuit routed via this string connector, and thermal runaway of the electrical energy store can be reliably prevented.

It is found to be advantageous if the electrical energy store comprises a protective device designed to additionally interrupt a flow of current between the electrical energy store and the at least one vehicle component when the fault circuit is detected. The protective device is designed to de-energize the electrical energy store. By way of example, the protective device may be integrated in the control device and can send a signal to the at least one vehicle component so that said vehicle component stops the current drain from the electrical energy store. The protective device can also comprise a fuse and/or a controllable switching device, for example having contactors, that disconnects the connections of the electrical energy store from the interconnection of strings and/or from connections of the at least one vehicle component. The protective device can be used to prevent the current from being relayed to the interconnection via the fault current path.

The embodiments presented with reference to the electrical energy store according to the disclosure, and the advantages of said embodiments, apply mutatis mutandis to the motor vehicle according to the disclosure.

Further features of the disclosure will emerge from the figures and the description of the figures. The features and combinations of features mentioned in the description hereinabove and the features and combinations of features mentioned in the description of the figures hereinbelow and/or in the figures alone can be used not only in the respectively indicated combination, but also in other combinations or on their own.

The disclosure is now explained in more detail on the basis of one or more preferred exemplary embodiments and with reference to the drawings.

### BRIEF DESCRIPTION OF THE DRAWINGS

FIG. 1 shows a schematic configuration of an electrical energy store for a motor

vehicle; and

FIG. 2 shows possible fault circuits of the electrical energy store in accordance

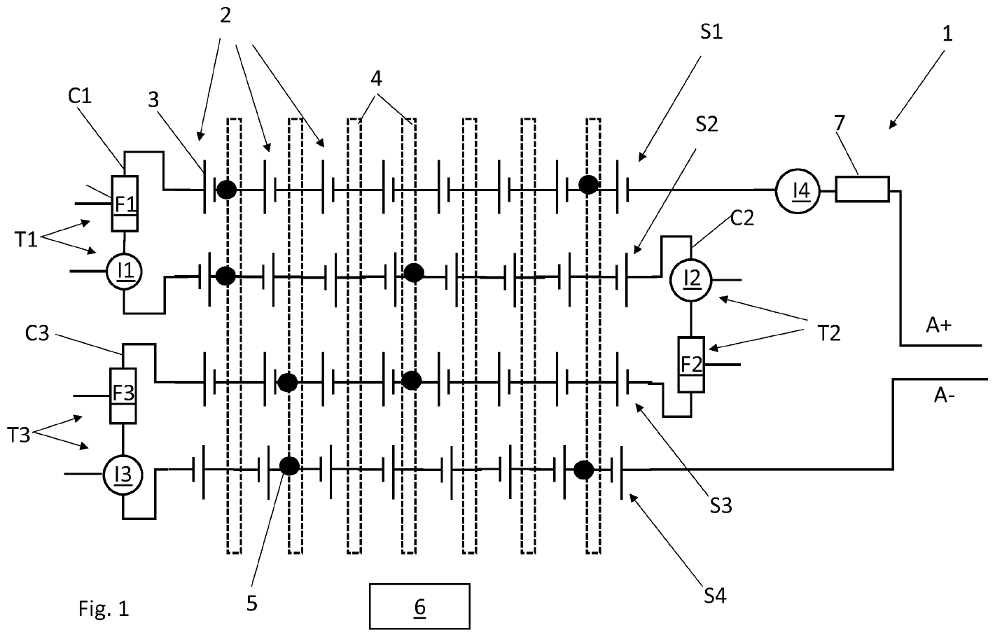

with FIG. 1.

### DETAILED DESCRIPTION OF THE DRAWINGS

In the figures, identical or functionally identical elements are provided with the same reference signs.

FIG. 1 shows an electrical energy store 1 that can be used for example as a rechargeable traction battery, or a traction accumulator, for an electric or hybrid vehicle. The electrical energy store 1 comprises connections A+, A− by way of which the electrical energy store 1 can be connected to at least one vehicle component of the motor vehicle. The electrical energy store 1 here comprises four store strings S1, S2, S3, S4 connected up in series that are arranged geometrically adjacently, or so as to run parallel. Each store string S1, S2, S3, S4 comprises multiple storage units 2, each of which comprises a storage cell 3 here. The storage units 2 and thus the storage cells 3 are connected up in series. The first store string S1 is connected to the first connection A+, here the positive pole, of the electrical energy store 1, and the fourth store string S4 is connected to the second connection A−, here the negative pole, of the electrical energy store 1. The first and second strings S1, S2 are connected in series by way of a first string connector C1. The second and third strings S2, S3 are connected in series by way of a second string connector C2 and the third and fourth strings S3, S4 are connected in series by way of a third string connector C3. The strings S1, S2, S3, S4 and the string connectors C1, C2, C3 produce a meandrous arrangement of the storage units 2.

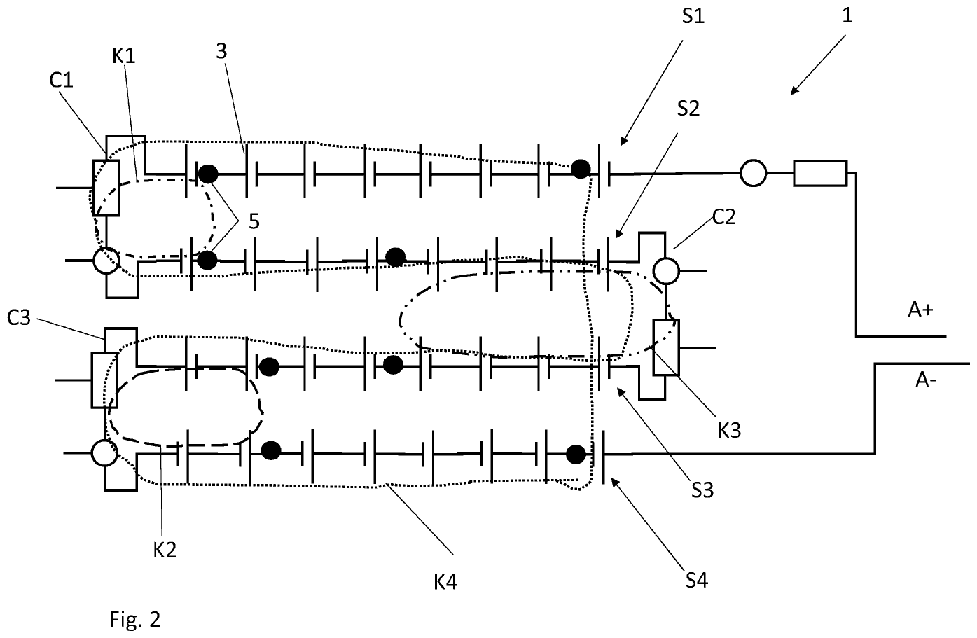

The electrical energy store 1 here additionally comprises multiple temperature control elements 4, which are arranged transversely with respect to the direction of extension of the strings S1, S2, S3, S4, and regions of which abut cell housings of the storage cells 3. The temperature control elements 4 may have points of failure 5, for example a defective insulation, that can result in undesirable electrical connections, or fault current paths, being formed between two store strings S1, S2, S3, S4. By way of example, a first connection between the first and second strings S1, S2 can be formed that produces a first fault circuit K1 with the first string connector C1. A second connection between the third and fourth strings S3, S4 can also be formed that produces a second fault circuit K2 with the third string connector C3. A third connection formed between the second and third strings S2, S3 can produce a third fault circuit K3 together with the second string connector C2. A fourth connection between the first and fourth strings S1, S4 can produce a fourth fault circuit K4 together with the string connectors C1, C2, C3. The fault circuits K1, K2, K3, K4 are shown in FIG. 2. The temperature control elements 4 are not shown in FIG. 2 for the sake of clarity. A respective fault current can circulate within these fault circuits K1, K2, K3, K4. This fault current circulating inside the store does not necessarily have to have a critical value, but it cannot drain from the electrical energy store 1 via the connections A+, A− and can thus lead to local overheating inside the electrical energy store 1.

Each of the string connectors C1, C2, C3 therefore comprises a disconnecting device T1, T2, T3. Each disconnecting device T1, T2, T3 comprises a current sensor I1, I2, I3 for recording a string current flowing via the string connector C1, C2, C3. Additionally, each disconnecting device T1, T2, T3 comprises a controllable disconnecting unit F1, F2, F3, which may be in the form of a pyro fuse, for example. The sensor data of the current sensors I1, I2, I3 can be received by a control device 6 that can also drive the disconnecting units F1, F2, F3. Additionally, the electrical energy store 1 here comprises a total current sensor 14 that can record the total current of the electrical energy store 1.

The control device 6 can now compare the string currents of the current sensors I1, I2, I3 with one another and with the total current of the current sensor I4. If for example the string current of the first current sensor I1 differs from the string currents of the other current sensors I2, I3 and from the total current of the total current sensor I4, the first fault circuit K1 is detected and the first disconnecting unit F1 is driven to disconnect the first string connector C1 and therefore to interrupt the first fault circuit K1. If for example the string current of the second current sensor I2 differs from the string currents of the other current sensors I1, I3 and from the total current of the total current sensor I4, the second fault circuit K2 is detected and the second disconnecting unit F2 is driven to disconnect the second string connector C2 and therefore to interrupt the second fault circuit K2. If for example the string current of the third current sensor I3 differs from the string currents of the other current sensors I1, I2 and from the total current of the total current sensor I4, the third fault circuit K3 is detected and the third disconnecting unit F3 is driven to disconnect the third string connector C3 and therefore to interrupt the third fault circuit K3. If for example the string currents of all current sensors I1, I2, I3 differ from the total current of the total current sensor I4, the fourth fault circuit K4 is detected and at least one of the disconnecting units F1, F2, F3 is driven to disconnect at least one string connector C1, C2, C3 and therefore to interrupt the fourth fault circuit K4.

If at least one of the fault circuits K4 has been detected, a protective device 7, for example a fuse, can additionally be driven to de-energize the electrical energy store 1.

1-9. (canceled)

10. An electrical energy store for a motor vehicle for supplying power to at least one vehicle component of the motor vehicle, comprising:
at least two geometrically adjacently extending store strings, each having multiple interconnected storage units that each comprise at least one storage cell;
at least one string connector configured to connect the store strings in series with a disconnecting device configured to detect and interrupt a fault circuit formed by an undesirable electrical connection between two store strings and the at least one string connector, the disconnecting device comprising a controllable disconnecting unit configured to disconnect the at least one string connector and a current sensor configured to record a string current flowing via the at least one string connector; and
a control device configured to take the recorded string current as a basis for detecting at least one fault circuit and driving the at least one controllable disconnecting unit to interrupt the fault circuit.

11. The electrical energy store according to claim 10, wherein:
the electrical energy store comprises a total current sensor configured to record a total current flowing through an interconnection of the store strings, wherein the control device is configured to compare the at least one string current with the total current and to detect the at least one fault circuit if the at least one string current differs from the total current by more than a predetermined threshold value.

12. The electrical energy store according to claim 10, wherein:
the electrical energy store comprises a protective device configured to additionally interrupt a flow of current between the electrical energy store and the at least one vehicle component when the at least one fault circuit is detected.

13. The electrical energy store according to claim 10, wherein:
the storage units per store string are arranged in a geometrically linear manner and each storage unit has at least one adjacent storage unit in a same store string and at least one adjacent storage unit in an adjacent store string.

14. The electrical energy store according to claim 10, wherein:
the electrical energy store comprises at least one temperature control element configured to control a temperature of the storage cells, wherein the temperature control element extends through the electrical energy store transversely with respect to a direction of extension of the store strings, and wherein the undesirable electrical connection occurs between at least two store strings based on insulation being faulty.

15. The electrical energy store according to claim 10, wherein:
the storage cells comprise round cells.

16. The electrical energy store according to claim 10, wherein:
the at least one controllable disconnecting unit comprises a pyro fuse configured to be ignited by the control device.

17. The electrical energy store according to claim 10, wherein:
the electrical energy store comprises at least three adjacently extending store strings that are connected in series by way of a respective string connector comprising a respective disconnecting device.

18. The electrical energy store according to claim 10, wherein the control device is configured to:
compare the string currents of the current sensor of the disconnecting device with one another and/or with a total current of the electrical energy store,
detect at least one fault circuit based on the comparing of the string currents, and
drive the controllable disconnecting unit of at least one relevant string connector to interrupt the fault circuit.

19. A motor vehicle comprising:
at least one vehicle component; and
at least one electrical energy store comprising:
at least two geometrically adjacently extending store strings, each having multiple interconnected storage units that each comprise at least one storage cell,
at least one string connector configured to connect the store strings in series with a disconnecting device configured to detect and interrupt a fault circuit formed by an undesirable electrical connection between two store strings and the at least one string connector, the disconnecting device comprising a controllable disconnecting unit configured to disconnect the at least one string connector and a current sensor configured to record a string current flowing via the at least one string connector; and
a control device configured to take the recorded string current as a basis for detecting at least one fault circuit and driving the at least one controllable disconnecting unit to interrupt the fault circuit.

20. The motor vehicle according to claim 19, wherein:
the electrical energy store comprises a total current sensor configured to record a total current flowing through an interconnection of the store strings, wherein the control device is configured to compare the at least one string current with the total current and to detect the at least one fault circuit if the at least one string current differs from the total current by more than a predetermined threshold value.

21. The motor vehicle according to claim 19, wherein:
the electrical energy store comprises a protective device configured to additionally interrupt a flow of current between the electrical energy store and the at least one vehicle component when the at least one fault circuit is detected.

22. The motor vehicle according to claim 19, wherein:
the storage units per store string are arranged in a geometrically linear manner and each storage unit has at least one adjacent storage unit in a same store string and at least one adjacent storage unit in an adjacent store string.

23. The motor vehicle according to claim 19, wherein:
the electrical energy store comprises at least one temperature control element configured to control a temperature of the storage cells, wherein the temperature control element extends through the electrical energy store transversely with respect to a direction of extension of the store strings, and wherein the undesirable electrical connection occurs between at least two store strings based on insulation being faulty.

24. The motor vehicle according to claim 19, wherein:
the storage cells comprise round cells.

25. The motor vehicle according to claim 19, wherein:
the at least one controllable disconnecting unit comprises a pyro fuse configured to be ignited by the control device.

26. The motor vehicle according to claim 19, wherein:
the electrical energy store comprises at least three adjacently extending store strings that are connected in series by way of a respective string connector comprising a respective disconnecting device.

27. The motor vehicle according to claim 19, wherein the control device is configured to:
compare the string currents of the current sensor of the disconnecting device with one another and/or with a total current of the electrical energy store,
detect at least one fault circuit based on the comparing of the string currents, and drive the controllable disconnecting unit of at least one relevant string connector to interrupt the fault circuit.
